(19) United States
(12) Patent Application Publication
(10) Pub. No.: US 2019/0185180 A1
(43) Pub. Date: Jun. 20, 2019

(54) SUPPORT PLATFORM FOR ACCOMMODATING A PORTABLE ELECTRONIC DEVICE IN AN AIRCRAFT

(71) Applicant: Airbus Operations SAS, Toulouse (FR)

(72) Inventor: Jean-Philippe CORBEFIN, MONDONVILLE (FR)

(21) Appl. No.: 16/216,609

(22) Filed: Dec. 11, 2018

(30) Foreign Application Priority Data
Dec. 18, 2017 (FR) 1762320

(51) Int. Cl. B64D 45/00; H05K 7/20

(52) U.S. Cl. CPC B64D 45/00; B64D 2045/0075; H05K 7/20863

(57) ABSTRACT

A support platform for accommodating a portable electronic device in an aircraft is configured to be fixed in the aircraft. It comprises an airtight closure arrangement configured to occupy at least an open position, in which the portable electronic device can be inserted in or removed from the support platform, and a closed position, in which the portable electronic device can be used by a user in the aircraft when the portable electronic device is inserted into the support platform.

### CROSS-REFERENCES TO RELATED APPLICATIONS

This application claims the benefit of the French patent application Ser. No. 1762320 filed on Dec. 18, 2017, the entire disclosures of which are incorporated herein by way of reference.

### BACKGROUND OF THE INVENTION

The present invention relates to the field of the use of portable electronic devices in an aircraft, in particular in an aircraft cockpit. Such portable electronic devices, for example of EFB (Electronic Flight Bag) type, are used commonly by crew members in the cockpit. These EFBs sometimes correspond to touch tablets powered by batteries incorporated in the tablets. These tablets are generally supplied to the crew members by the airline operating the aircraft. They do not, then, correspond to hardware certified by the air certification authorities. Sometimes, the crew members are also required to introduce personal smartphones into the cockpit that are also powered by batteries. Now, it is known that the batteries powering the portable smartphones or the tablets can sometimes present a fire risk, in particular the batteries that include lithium. There is, therefore, a need to protect the aircraft from a fire risk due to such portable electronic devices, while allowing the use of the devices.

### SUMMARY OF THE INVENTION

The aim of the present invention is, in particular, to provide a solution to this need. It relates to a support platform for accommodating a portable electronic device in an aircraft, in particular in a cockpit of the aircraft, the support platform being designed to be fixed in the aircraft.

The support platform is noteworthy in that it comprises an airtight closure means configured to occupy at least a first, so-called open position, in which the portable electronic device can be inserted in or removed from the support platform, and a second, so-called closed position, in which the portable electronic device can be used by a user in the aircraft, in particular in the cockpit of the aircraft, when the portable electronic device is inserted into the support platform, the support platform being fixed in the aircraft, in particular, in the cockpit of the aircraft.

The support platform thus allows a user of a portable electronic device to place this portable electronic device inside the support platform, then to place the closure means in the closed position to use the portable electronic device. Thus, the portable electronic device is placed in the support platform that is closed in an airtight manner when the user uses this portable electronic device. That makes it possible to protect the aircraft, in particular the cockpit of the aircraft, and the crew members in case of fire and/or the release of smoke originating from the portable electronic device.

Advantageously, the support platform comprises a cooling system that can be commanded between a first, so-called active position, in which the cooling system allows a circulation of air between the interior and the exterior of the support platform, and a second, so-called inactive position, in which the cooling system prevents the circulation of air between the interior and the exterior of the support platform. This cooling system makes it possible to discharge the heat from the portable electronic device.

According to a first variant, the cooling system comprises a mechanical means designed to manually command a switchover between its active position and its inactive position or vice versa.

According to a second variant, the cooling system comprises:
a sensor provided to detect a degraded environmental condition inside the support platform;
an actuator configured to command the active position or the inactive position of the cooling system; and
a processing unit linked to an output of the sensor and configured to command the actuator so as to command the active position of the cooling system when the sensor detects a degraded environmental condition.

In a particular embodiment, the support platform comprises a heat exchanger provided to discharge the heat from the portable electronic device out of the support platform. In particular, the heat exchanger corresponds to a heat pipe or to a Peltier effect device.

Advantageously, the support platform comprises a transparent wall allowing a user to see a screen of the portable electronic device through the wall.

More advantageously, the support platform comprises an outer screen configured to copy a display of a screen of the portable electronic device when the latter is inserted into the support platform.

In one embodiment, the support platform comprises means for connecting the portable electronic device to a communication network of the aircraft.

In one embodiment, the support platform comprises electrical power supply means for the portable electronic device.

The invention relates also to an aircraft comprising a support platform as cited above.

### BRIEF DESCRIPTION OF THE DRAWINGS

The invention will be better understood on reading the following description and on studying the attached figures.

FIG. 1 represents an aircraft comprising a cockpit;

FIG. 2 is a simplified perspective view of a support platform according to an embodiment of the invention;

FIG. 3 is a cross-sectional view along the line A-A of FIG. 2.

### DETAILED DESCRIPTION OF THE PREFERRED EMBODIMENTS

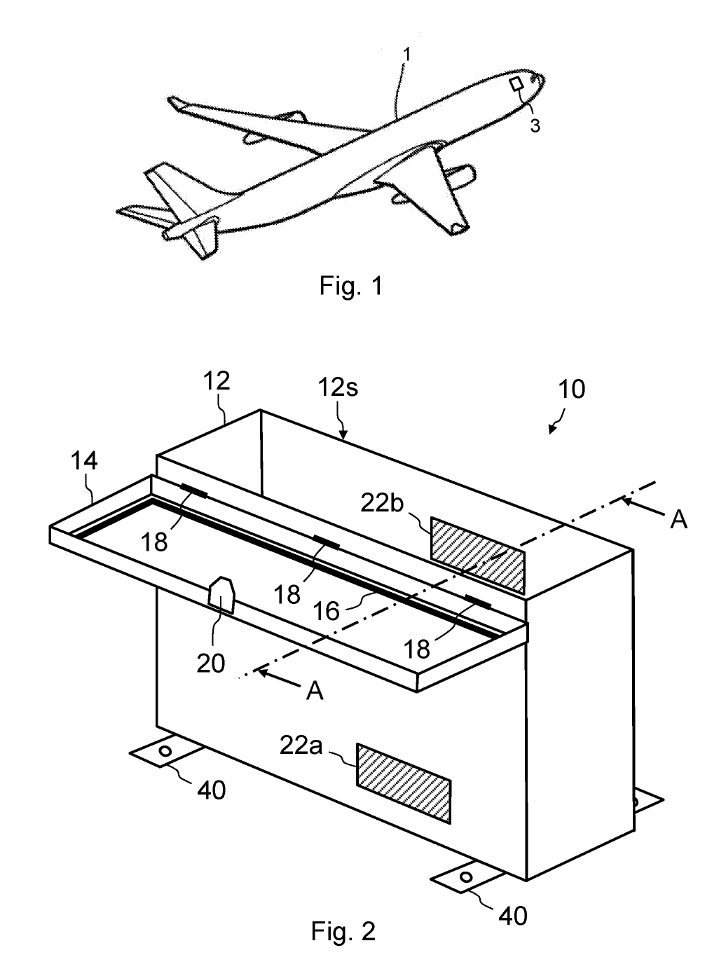

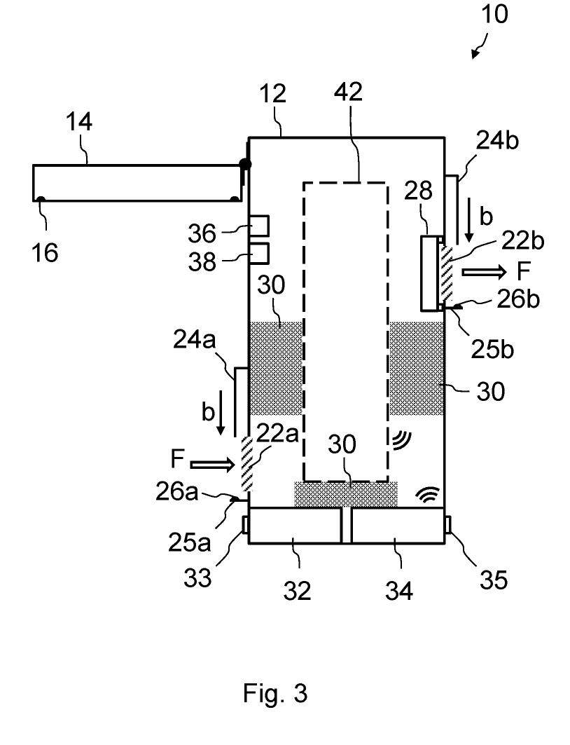

The support platform 10 represented in FIGS. 2 and 3 comprises a receptacle 12 and a closure corresponding to a cover 14. The cover 14 comprises a seal 16 provided to cooperate with a top part 12s of the receptacle 12. This cover 14 is articulated on the receptacle 12 by means of a set of hinges 18 so that it can occupy at least an open position, as represented in the figures and a closed position in which this cover forms an airtight closure means for the support platform 10. A lock 20 integral to the cover 14 is provided to cooperate with a locking means that is not represented, secured to the receptacle 12, so as to keep the cover 14 in closed position. The support platform 10 comprises fixing means 40, for example fixing tabs, making it possible to fix it in a cockpit 3 of an aircraft 1 such as that represented in FIG. 1. The receptacle 12 is provided to receive a portable electronic device 42, such as, for example, a portable computer, a touch tablet or a portable smartphone.

When the cover 14 is in open position, a crew member of the aircraft can insert or remove the portable electronic device 42 into or from the receptacle 12 of the support platform 10. Once the portable electronic device 42 is inserted into the receptacle 12, the crew member can maneuver the cover 14 so as to bring it into closed position. The portable electronic device 42 is thus enclosed in the support platform 10 which constitutes an airtight enclosure. That makes it possible to protect the cockpit 3 of the aircraft and the crew members in case of fire and/or release of smoke originating from the portable electronic device.

The support platform 10 is provided to allow the use of the portable electronic device 42 by a crew member when the portable electronic device 42 is inserted into and enclosed in the support platform 10.

In one embodiment, the support platform 10 comprises communication means 34 provided to allow the portable electronic device 42, enclosed in the support platform 10, to communicate with the outside of the support platform 10. The communication between the portable electronic device 42 and the communication means 34 can be of wired type or of wireless type (for example of WiFi type or of LiFi type) as represented in FIG. 3. Advantageously, the communication means 34 are configured to allow a connection of the portable electronic device to a communication network of the aircraft. This communication can be of wireless type (for example of WiFi type) or of wired type (for example of Ethernet type). In such a case, the communication means 34 comprise a connector 35 making it possible to connect them to this communication network of the aircraft. More advantageously, the communication means 34 comprise a switch and/or a router. The connection of the portable electronic device 42 to the communication network of the aircraft allows the acquisition, by the portable electronic device 42 enclosed in the support platform 10, of information from avionics systems of the aircraft. This connection can also allow control of the portable electronic device 42 by control means of the cockpit 3, for example of keyboard and/or trackball type, as well as a relaying of the display of the portable electronic device 42 onto a screen of the cockpit 3 of the aircraft.

In a particular embodiment, the receptacle 12 comprises a transparent wall allowing a user such as a crew member to see a screen of the portable electronic device 42 through the wall. This transparent wall advantageously comprises a touch surface allowing interaction with the portable electronic device 42. In another particular embodiment, the support platform comprises an outer screen configured to copy a display of a screen of the portable electronic device 42 when the latter is inserted into the support platform. This screen is, for example, linked to the portable electronic device 42 via the communication means 34. Advantageously, this screen is of touch type, allowing the crew member to control the portable electronic device 42. According to an alternative, this screen is fixed directly onto the support platform 10. According to another alternative, it is placed in the cockpit 3 of the aircraft and linked by a wired link to the support platform 10.

According to one embodiment, the support platform 10 comprises an electrical power supply 32 receiving electrical energy from an electrical network of the aircraft, for example via an electrical connector 33. This electrical power supply 32 is provided to electrically power the portable electronic device 42 when the latter is inserted into the receptacle 12. The portable electronic device 42 can thus be used even if its incorporated battery is not sufficiently charged. According to an alternative, the portable electronic device 42 is linked to the electrical power supply 32 by a wired link, for example via a connector of USB type. According to another alternative, the portable electronic device 42 is inductively coupled to the electrical power supply 32, which avoids the use of a wired link.

Advantageously, the support platform 10 is provided with a means to discharge the heat dissipated by the portable electronic device 42. For that, in a first embodiment, the support platform 10 comprises a cooling system which comprises a set of vents allowing a circulation of the air in the receptacle. For example, as represented in FIGS. 2 and 3, the receptacle 12 comprises vents 22a, 22b. The vent 22a is placed in the bottom part of a first face of the receptacle 12 and the vent 22b is placed in the top part of a second face of the receptacle, opposite the first face, which allows a circulation of the air from the vent 22a to the vent 22b, around the portable electronic device 42 as illustrated by the arrows F in FIG. 3. The heat dissipated by the portable electronic device 42 is thus discharged out of the support platform 10. The vents 22a and 22b comprise, for example, a set of chicanes. Advantageously, the support platform 10 can also comprise a fan 28 making it possible to improve the circulation of air in the receptacle 12 between the vent 22a and the vent 22b. The support platform 10 also comprises means for blocking the vents 22a and 22b. These blocking means comprise, for example, first parts 25a, 25b that are fixed relative to the receptacle 12 and second parts 24a, 24b that are mobile relative to the receptacle 12 as illustrated by the arrows b. In their positions illustrated in FIG. 3, the second parts 24a, 24b allow the passage of the air between the interior and the exterior of the support platform 10 through the vents 22a, 22b, which corresponds to a first, so-called active position of the cooling system, in which the cooling system allows a circulation of air between the interior and the exterior of the support platform. The second parts 24a, 24b can be translated according to the arrows b such that an end of the second parts 24a, 24b comes into contact respectively with the first parts 25a, 25b. Advantageously, the first parts 25a, 25b are provided with a seal, respectively 26a, 26b. The blocking means then block the passage of the air in line with the vents 22a, 22b, which corresponds to a second, so-called inactive position of the cooling system, in which the cooling system prevents the circulation of air between the interior and the exterior of the support platform.

The cooling system can thus be commanded between, on the one hand, the first, active position in which it allows a circulation of air between the interior and the exterior of the support platform and, on the other hand, the second, inactive position, in which it prevents the circulation of air between the interior and the exterior of the support platform. In a first alternative, the cooling system comprises a mechanical means provided to manually command a switchover between its active position and its inactive position or vice versa. This mechanical means corresponds, for example, to a handle or to a lever making it possible to maneuver the second parts 24a, 24b according to the arrows b represented in FIG. 3. This mechanical means is advantageously common to the two second parts 24a and 24b. It is however possible to provide an individual command means for each of the second parts 24a and 24b. In normal operation, a crew member places the mechanical means so that the cooling system is in its active position. If the crew member detects a start of fire on the portable electronic device or a release of smoke, he or she actuates the mechanical means so as to place the cooling system in its inactive position. The cockpit of the aircraft is then protected from the fire or from the release of smoke.

In a second alternative, the cooling system comprises a sensor provided to detect a degraded environmental condition inside the support platform 10. This sensor corresponds, for example, to a temperature sensor 36 making it possible to detect a temperature rise and/or a smoke sensor 38 making it possible to detect a release of smoke in the support platform 10. The cooling system also comprises an actuator configured to command the active position or the inactive position of the cooling system, as well as a processing unit. The processing unit is linked to an output of the sensor or sensors 36, 38 and it is configured to command the actuator so as to command the active position of the cooling system when the sensor or sensors detect a degraded environmental condition in the support platform 10, such as a temperature rise and/or a release of smoke. That makes it possible to automatically protect the cockpit of the aircraft in case of fire or of release of smoke.

In a second embodiment, the support platform 10 comprises a heat exchanger provided to discharge the heat from the portable electronic device 42 out of the support platform. This heat exchanger is preferably placed against a wall of the receptacle 12. It corresponds, for example, to a heat pipe or to a Peltier effect device. Such a heat exchanger offers the advantage of not requiring a circulation of air between the interior and the exterior of the support platform.

In a particular embodiment, the walls of the receptacle 12 and of the cover 14 are metal so as to allow an at least partial Faraday-caging of the interior of the support platform. As a variant, these walls are produced in a non-metal material, for example a composite material, incorporating a metal lattice or covered by a metal lattice so as to allow an at least partial Faraday-caging of the interior of the support platform.

In a particular embodiment, the receptacle 12 also comprises a set of shims 30 making it possible to secure the portable electronic device 42 in position. These shims are, for example, produced in a flexible material such as foam, also making it possible also to protect the portable electronic device.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

The invention claimed is:

1. A support platform for accommodating a portable electronic device of Electronic Flight Bag type in an aircraft, the support platform being configured to be fixed in the aircraft, comprising an airtight closure configured to occupy at least a first, open position, in which the portable electronic device is insertable in or removable from the support platform, and a second, closed position, in which the portable electronic device is usable by a user in the aircraft when the portable electronic device is inserted into the support platform, the support platform being fixed in the aircraft.

2. The support platform according to claim 1, further comprising a cooling system commandable between a first active position, in which the cooling system allows a circulation of air between the interior and the exterior of the support platform, and a second inactive position, in which the cooling system prevents the circulation of air between the interior and the exterior of the support platform.

3. The support platform according to claim 2, wherein the cooling system comprises a mechanical means provided to manually command a switchover between its active position and its inactive position or vice versa.

4. The support platform according to claim 2, wherein the cooling system comprises:
a sensor provided to detect a degraded environmental condition inside the support platform;
an actuator configured to command the active position or the inactive position of the cooling system; and
a processing unit linked to an output of the sensor and configured to command the actuator so as to command the active position of the cooling system when the sensor detects the degraded environmental condition.

5. The support platform according to claim 1, further comprising a heat exchanger configured to discharge heat from the portable electronic device out of the support platform.

6. The support platform according to claim 1, further comprising a transparent wall allowing a user to see a screen of the portable electronic device through said wall.

7. The support platform according to claim 1, further comprising an outer screen configured to copy a display of a screen of the portable electronic device when the electronic device is inserted into the support platform.

8. The support platform according to claim 1, further comprising connector configured to connect the portable electronic device to a communication network of the aircraft.

9. The support platform according to claim 8, wherein the connector comprises a wireless communications connector.

10. The support platform according to claim 8, wherein the connector comprises a wired communications connector.

11. The support platform according to claim 1, further comprising an electrical power supply for the portable electronic device.

12. An aircraft comprising a support platform according to claim 1.
